(19) United States
(12) Patent Application Publication
(10) Pub. No.: US 2024/0141503 A1
(43) Pub. Date: May 2, 2024

(54) METHOD OF APPLYING A DIELECTRIC COATING ON A COMPONENT OF AN ELECTRICAL DEVICE

(71) Applicant: Quantinuum LLC, Broomfield, CO (US)

(72) Inventors: Christopher Todd Ertsgaard, Champlin, MN (US); Adam Jay Ollanik, Boulder, CO (US); Todd Michael Klein, Wayzata, MN (US); John Snyder, Edina, MN (US); Ryan Patrick Shea, Elko New Market, MN (US); Christopher Todd DeRose, Albuquerque, NM (US); Michael Ryan Gehl, Tijeras, NM (US)

(21) Appl. No.: 18/498,493

(22) Filed: Oct. 31, 2023

Related U.S. Application Data
(60) Provisional application No. 63/382,040, filed on Nov. 2, 2022.

(51) Int. Cl. C23C 28/04; C23C 16/40; C23C 16/455

(52) U.S. Cl. CPC C23C 28/04; C23C 16/402; C23C 16/45529; G02B 6/13

(57) ABSTRACT

A method of applying a dielectric coating on a structure array of a component of an electrical device includes applying a first layer of a first dielectric material on a structure array with an atomic layer deposition (ALD) process or a spin-on cladding process. The structure array has a plurality of features. The method may include applying a second layer of a second dielectric material on the first layer with an evaporation deposition process, a physical vapor deposition process (PVD), or a flux-controlled chemical vapor deposition (CVD) process. The first layer has a first thickness and the second layer has a second thickness that is greater than the first thickness.

### CROSS-REFERENCE TO RELATED APPLICATIONS

This application claims the benefit of U.S. Provisional Patent Application No. 63/382,040, filed Nov. 2, 2022, the entire contents of which are incorporated by reference herein.

### STATEMENT REGARDING FEDERALLY SPONSORED RESEARCH

This invention was made under a CRADA SC20/01973.00.01/PTS 1973.02.01 between Quantinuum LLC and National Technology & Engineering Solutions of Sandia, LLC operated for the United States Department of Energy. The Government has certain rights in this invention.

### TECHNICAL FIELD

Various embodiments relate to apparatuses, systems, and methods relating to a dielectric coating on a component of an electrical device. An example embodiment relates to a dielectric coating on a structure array of an integrated optical component of an ion trap.

### BACKGROUND

Components for electrical devices, such as an integrated optical component for an ion trap, often include a thick dielectric coating that is applied on the substrate of the component. The thick dielectric coating has traditionally been applied on the substrate of the component with a flux-controlled chemical vapor deposition process. Applying a dielectric coating on surfaces that include features that have a high aspect ratio can be challenging and may result in flaws or defects. Through applied effort, ingenuity, and innovation many deficiencies of prior dielectric coating formation techniques have been solved by developing solutions that are structured in accordance with the embodiments of the present invention, many examples of which are described in detail herein.

### BRIEF SUMMARY OF EXAMPLE EMBODIMENTS

Example embodiments provide methods for applying a dielectric coating on a structure array of a component of an electrical device. In various example embodiments, the structure array is formed of a plurality of features formed on a substrate or one or more sublayers formed on the substrate. In various example embodiments, each of and/or at least some of the plurality of features have an aspect ratio of at least 1:1. In various example embodiments, the electrical device is an ion trap and the component is an integrated optical component of the ion trap.

According to an aspect of the present disclosure, a method for applying a dielectric coating on a structure array of a component is provided. In various example embodiments, the method of applying the dielectric coating on the structure array of the component includes applying a first layer of a first dielectric material on the structure array with a spin-on cladding process, the first layer having a first thickness.

In various example embodiments, the method further includes applying a second layer of a second dielectric material on the first layer with an evaporation deposition process, a physical vapor deposition process (PVD), or a flux-controlled chemical vapor deposition (CVD) process.

In various example embodiments, the method further includes removing at least a portion of the first layer with an etching process.

In various example embodiments, the second layer of the second dielectric material is applied on the first layer with a plasma-enhanced chemical vapor deposition (PECVD) process.

In various example embodiments, the second layer has a second thickness that is greater than the first thickness.

In various example embodiments, the first thickness is less than or equal to 300 nanometers (nm) and the second thickness is greater than or equal to 5,000 nm.

In various example embodiments, at least one of the features of the plurality of features is spaced apart from another one of the plurality of features by a distance, wherein a ratio between the first thickness of the first layer and the distance is at least 0.4:1 and up to 0.6:1.

In various example embodiments, a ratio between the second thickness and the first thickness is at least 100:1 and up to 300:1.

In various example embodiments, at least one of the first dielectric material or the second dielectric material includes silicon dioxide (SiO2).

In various example embodiments, the first dielectric material and the second material are the same.

In various example embodiments, the first dielectric material and the second material include SiO2.

In various example embodiments, the first dielectric material and the second dielectric material are different.

In various example embodiments, either the first dielectric material or the second dielectric material is SiO2, but not both.

In various example embodiments, neither the first dielectric material nor the second dielectric material is SiO2.

In various example embodiments, at least one of the first dielectric material or the second dielectric material includes titanium dioxide (TiO2), aluminum oxide (Al2O3), or hafnium oxide (HfO2).

In various example embodiments, the first dielectric material and the second dielectric material includes TiO2, Al2O3, or HfO2.

In various example embodiments, one of the first dielectric material or the second dielectric material includes SiO2, the other of the first dielectric material or the second dielectric material includes TiO2, Al2O3, or HfO2.

In various example embodiments, at least one of the substrate or the structure array includes at least one of Aluminum Oxide (Al2O3), Titanium dioxide (TiO2), silicon (Si), or silicon nitride (Si3N4).

In various example embodiments, the method further includes performing chemical mechanical planarization on the first layer prior to applying the second layer of the second dielectric material on the first layer.

In various example embodiments, the spin-on cladding process is an ion beam spin-on glass process.

In various example embodiments, the method further includes performing chemical mechanical planarization on the second layer.

In various example embodiments, the method further includes depositing a first electrode on the first layer and depositing a second electrode on the second layer.

In various example embodiments, the method further includes depositing a first electrode on the second layer, applying a third layer of a third dielectric material on the second layer with an evaporation deposition process, a PVD process, or a flux-controlled CVD process, and depositing a second electrode on the third layer.

In various example embodiments, the first electrode is a ground electrode of an ion trap and the second electrode is a control electrode of the ion trap.

In various example embodiments, the first electrode is a ground electrode, a radio frequency drive electrode, or a control electrode.

In various example embodiments, the second electrode is a ground electrode, a radio frequency drive electrode, or a control electrode.

In various example embodiments, a first distance is defined by at least a first pair of adjacent features of the plurality of features and a second distance is defined by at least a second pair of adjacent features of the plurality of features, and wherein the second distance is greater than the first distance.

According to an aspect of the present disclosure, a method for applying a dielectric coating on a structure array of a component is provided. In various example embodiments, the method of applying the dielectric coating on the structure array of the component includes applying a first layer of a first dielectric material on the structure array with an atomic layer deposition (ALD) process or a spin-on cladding process, the first layer having a first thickness.

In various example embodiments, the method further includes applying a second layer of a second dielectric material on the first layer with a plasma-enhanced chemical vapor deposition (PECVD) process.

In various example embodiments, the second layer has a second thickness that is greater than the first thickness.

In various example embodiments, the first thickness is less than or equal to 300 nanometers (nm) and the second thickness is greater than or equal to 5,000 nm.

In various example embodiments, the method further includes removing at least a portion of the first layer with an etching process.

In various example embodiments, at least one of the features of the plurality of features is spaced apart from another one of the plurality of features by a distance, wherein a ratio between the first thickness of the first layer and the distance is at least 0.4:1 and up to 0.6:1.

In various example embodiments, a first distance is defined by at least a first pair of adjacent features of the plurality of features and a second distance is defined by at least a second pair of adjacent features of the plurality of features, and wherein the second distance is greater than the first distance.

In various example embodiments, at least one of the first dielectric material or the second dielectric material comprises silicon dioxide (SiO2).

In various example embodiments, at least one of the first dielectric material or the second dielectric material comprises titanium dioxide (TiO2), aluminum oxide (Al2O3), or hafnium oxide (HfO2).

In various example embodiments, the electrical device is an ion trap and the component is a photonic component of the ion trap.

In various example embodiments, the first thickness is less than or equal to 300 nanometers (nm), and wherein the second thickness is greater than or equal to 5,000 nm and less than or equal to 25,000 nm.

In various example embodiments, a ratio between the second thickness and the first thickness is at least 100:1 and up to 300:1.

According to another aspect, an electrical device is provided. In an example embodiment, the electric device includes a component. The component includes a structure array and a dielectric coating disposed on the structure array. The structure array includes a plurality of features with each of the plurality of features having an aspect ratio of at least 1:1. The dielectric coating comprises a first layer of a first dielectric material having a first thickness and a first refractive index; and a second layer of a second dielectric material having a second thickness and a second refractive index, wherein the second thickness is greater than the first layer thickness. The first layer is positioned between the structure array and the second layer, and a percent difference between the first refractive index and the second refractive index is greater than 0 and up to 0.5 percent.

In various example embodiments, the first refractive index of the first layer is substantially uniform throughout the first layer.

In various example embodiments, the second refractive index of the second layer is substantially uniform throughout the second layer.

In various example embodiments, the component further includes a first electrode positioned between the first layer and the second layer.

In various example embodiments, the component further includes a second electrode positioned on the second layer.

In various example embodiments, at least one of the features of the plurality of features is spaced apart from another one of the plurality of features by a distance, wherein a ratio between the first thickness of the first layer and the distance is at least 0.4:1 and up to 0.6:1.

In various example embodiments, a first distance is defined by at least a first pair of adjacent features of the plurality of features and a second distance is defined by at least a second pair of adjacent features of the plurality of features, and wherein the second distance is greater than the first distance.

In various example embodiments, at least one of the first dielectric material or the second dielectric material comprises silicon dioxide (SiO2).

In various example embodiments, the first dielectric material and the second dielectric material are the same.

In various example embodiments, the first dielectric material and the second dielectric material are different.

In various example embodiments, the component comprises a substrate, the substrate comprising at least one of Aluminum Oxide (Al2O3), Titanium dioxide (TiO2), silicon (Si), or silicon nitride (Si3N4).

In various example embodiments, the electrical device is an ion trap and the component is a photonic component of the ion trap.

In various example embodiments, the first thickness is less than or equal to 300 nanometers (nm), and wherein the second thickness is greater than or equal to 5,000 nm and less than or equal to 20,000 nm.

### BRIEF DESCRIPTION OF THE SEVERAL VIEWS OF THE DRAWINGS

Having thus described the invention in general terms, reference will now be made to the accompanying drawings, which are not necessarily drawn to scale, and wherein:

FIG. 1 is a schematic diagram of an electrical device, according to an example embodiment.

FIG. 2A is a schematic diagram of a component of an electrical device, according to an example embodiment.

FIG. 2A is a schematic diagram of a component of an electrical device, according to an example embodiment.

FIG. 2B is a schematic diagram of a component of an electrical device, according to an example embodiment.

FIG. 2C is a schematic diagram of a component of an electrical device, according to an example embodiment.

FIG. 3A and FIG. 3B are schematic views of a portion of a component with a prior art dielectric coating disposed on the portion of the component.

FIG. 4A is a schematic diagram of a component of an electrical device, according to an example embodiment.

FIG. 4B is a schematic diagram of a component of an electrical device, according to an example embodiment.

FIG. 5 is a schematic diagram of a component of an electrical device, according to an example embodiment.

FIG. 6 is a schematic diagram of a component of an electrical device, according to an example embodiment.

FIG. 7 is a schematic diagram of an electrical device, according to an example embodiment.

FIG. 8A is a flowchart of a method of applying a dielectric coating on a component, according to an example embodiment.

FIG. 8B is a flowchart of a method of applying a dielectric coating on a component, according to an example embodiment.

FIG. 9 is a flowchart of a method of applying a dielectric coating on a component, according to an example embodiment.

FIG. 10 is a flowchart of a method of applying a dielectric coating on a component, according to an example embodiment.

### DETAILED DESCRIPTION OF SOME EXAMPLE EMBODIMENTS

The present invention now will be described more fully hereinafter with reference to the accompanying drawings, in which some, but not all embodiments of the invention are shown. Indeed, the invention may be embodied in many different forms and should not be construed as limited to the embodiments set forth herein; rather, these embodiments are provided so that this disclosure will satisfy applicable legal requirements. The term “or” (also denoted “/”) is used herein in both the alternative and conjunctive sense, unless otherwise indicated. The terms “illustrative” and “exemplary” are used to be examples with no indication of quality level. The terms “generally,” “substantially,” and “approximately” refer to within engineering and/or manufacturing tolerances and/or within user measurement capabilities, unless otherwise indicated. Like numbers refer to like elements throughout.

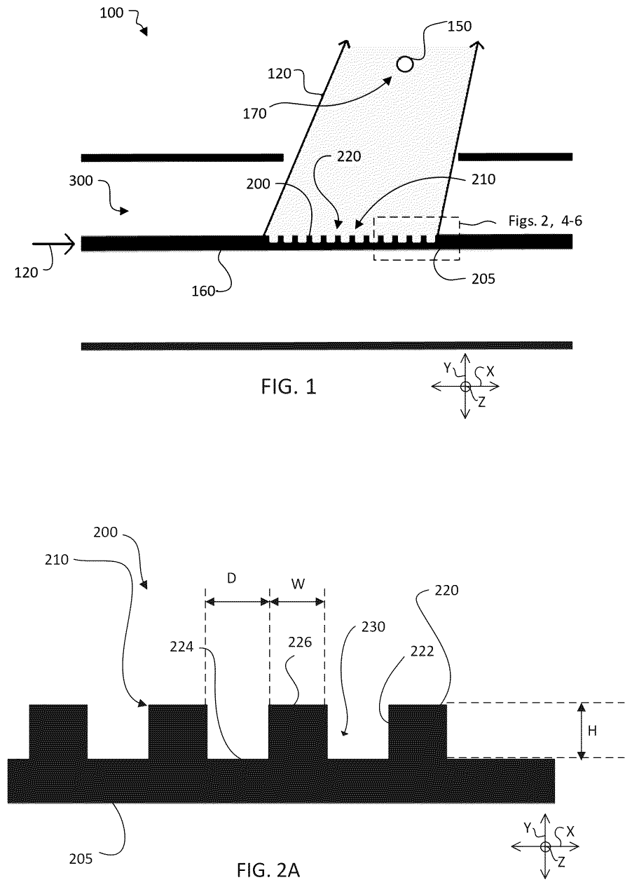

Referring now to FIG. 1, a schematic diagram of an electrical device 100 is provided, according to an example embodiment. The electrical device 100 defines an X direction, a Y direction that is orthogonal to the X direction, and a Z direction (in and out of page) that is orthogonal to the X direction and the Y direction. As shown, the electrical device 100 includes a component 200. The component 200 can include a structure array 210 that is formed on, or integrally with, a substrate 205 of the component 200. In various examples, the component includes sublayers on the substrate 205 that the structure array 210 is formed on, or integrally with. The structure array 210 can include a plurality of features 220. Additionally, the component 200 can include a dielectric coating 300 that is disposed on the structure array 210 of the component 200.

As will be discussed further, applying a dielectric coating 300 with traditional methods may result in flaws and/or defects. For example, applying the dielectric coating 300 with traditional methods may cause voids or keyholes to be present in the dielectric coating 300. These flaws and/or defects may cause the refractive index of the dielectric coating 300 to be inconsistent and/or non-uniform throughout the dielectric coating 300, leading to optical loss of optical beams passing there through. The methods, as described herein, may result in the reduction and/or elimination of these defects and/or flaws. As a result, the methods, as described herein, may result in applying a dielectric coating 300 to a component 200 that is more uniform and/or has a more consistent refractive index of the dielectric coating 300.

In the example of FIG. 1, the electrical device 100 is an ion trap, which may be configured to trap at least one atomic ion 150. The electrical device 100 can include a waveguide 160 that may route light 120 from at least one laser beam to the component 200. In various examples, the component 200 is a photonic component or an integrated optical component. For example, the component 200 can be a photonic component, such as a photonic coupling element, which may be a device that couples light from a guided mode to a free space propagating mode. The component 200 may be a diffraction grating of the ion trap, which can be integrated into the ion trap to focus and direct the light 120 from the at least one laser beam to the trapping zone 170 to trap the at least one atomic ion 150. In various examples, the grating or the photonic component is etched onto the substrate 205 of the component 200 or on one or more sublayers formed on the substrate 205 of the component 200.

Even though various examples are and will be provided where the electrical device 100 is an ion trap and the component 200 is an integrated optical component (e.g., a photonic component, such as a photonic coupling element) for the ion trap, it should be understood that other examples of the electrical device 100 and the component 200 are contemplated. For example, the component 200 can be a photonic component, such as a metasurface for an optical device. For example, the component 200 can be a lens, a quarter or half waveplate metasurface, a spatial beam shaping metasurface, a beam directing metasurface, a lens for an image sensor, a camera, a microscope, a laser beam splitter, or a color filter. In various examples, the component 200 can be a diffractive optic-phase-array or a hologram (e.g., lens hologram, graded arrays for beam direction, or spatial beam shaping holograms). In yet other examples, the component 200 can be a metasurface for an antenna or a sound absorbing device. In yet other examples, the component 200 can be a ring resonator, a power modulator, a waveguide, an input taper, a splitter (e.g., multi-mode interference (MMI), or y-branch), or a directional coupler.

In various examples, the substrate 205 can be formed from a dielectric material. For example, the substrate 205 can be formed from at least one of Aluminum Oxide (Al2O3), Titanium dioxide (TiO2), silicon (Si), or silicon nitride (Si3N4). In various examples, the structure array 210 and/or the plurality of features 220 can be formed from a dielectric material. For example, the structure array 210 and/or the plurality of features 220 can be formed from at least one of Al2O3, TiO2, Si, or Si3N4. Additionally, the dielectric coating 300 can be formed from a dielectric material. For example, the dielectric coating 300 can be formed from or include silicon dioxide (SiO2), titanium dioxide (TiO2), aluminum oxide (Al2O3), or hafnium oxide (HfO2).

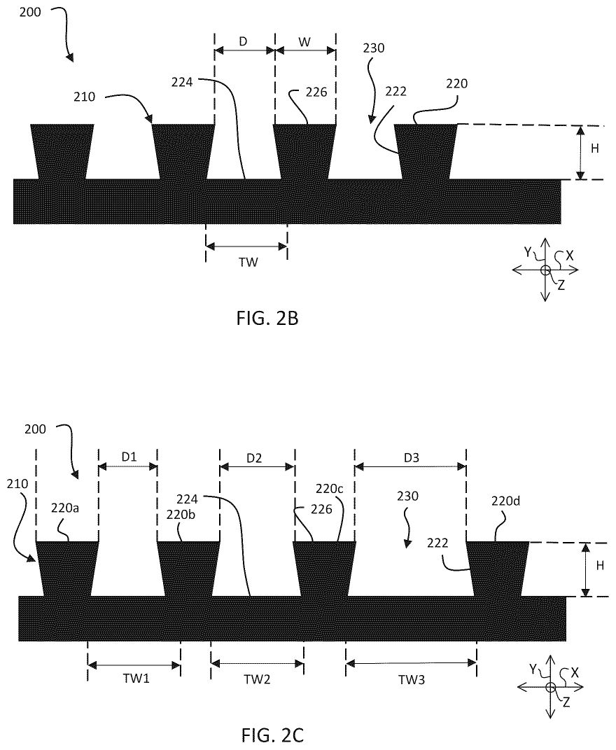

Referring now to FIG. 2A, a schematic diagram of a component 200 of an electrical device 100 is provided, according to an example embodiment. As mentioned, the component 200 can include a structure array 210, and the structure array 210 can include a plurality of features 220. Each of the plurality of features 220 can define a ridge 226 that extends generally in the X direction. Additionally, each of the plurality of features 220 can define at least two walls 222 that each extend generally in the Y direction. The structure array 210 can define one or more bottoms 224 that are disposed between at least two of the features 220 of the plurality of features 220. Additionally, the structure array 210 can define at least one trench 230 that is defined between two adjacent features 220. Each of the plurality of features 220 can have a height H and a width W and can have an aspect ratio (H:W). Also, each of the plurality of features 220 can be spaced apart from an adjacent feature of the plurality of features 220 by a distance D.

Referring now to FIG. 2B, a schematic diagram of a component 200 of an electrical device 100 is provided, according to an example embodiment. In various examples, each of the plurality of features 220 can define at least one wall 222, such as at least two walls 222, that extend at an acute angle relative to the X direction (also referred herein as a “re-entrant profile”). The trench 230 that is defined between two adjacent features 220 can generally have a cross-sectional trapezoid shape, such as a cross-sectional, isosceles trapezoid shape. The ridges 226 of adjacent features 220 may define the distance D between the adjacent features of the plurality of features 220. The bottom 224 that is disposed between two of the features 220 can define a trench width TW. The trench width TW defined between two of the features 220 can be greater than the distance D defined between those features.

Referring now to FIG. 2C, a schematic diagram of a component 200 of an electrical device 100 is provided, according to an example embodiment. In various examples, a distance D between adjacent features 220 of the plurality of features 220 may be varied. For example, a first feature 220a and an adjacent second feature 220b can define a first distance D1, whereas the second feature 220b and an adjacent third feature 220c can define a second distance D2 that is not equal to the first distance D1. In various examples, the third feature 220c and an adjacent fourth feature 220d can define a third distance D3 that is not equal to the first distance D1 or the second distance D2. Similarly, a trench width TW defined between adjacent features 220 of the plurality of features 200 may be varied. For example, the first feature 220a and the adjacent second feature 220b can define a first trench width TW1, whereas the second feature 220b and the adjacent third feature 220c can define a second trench width TW2 that is not equal to the first trench width TW1. In various examples, the third feature 220c and the adjacent fourth feature 220d can define a third trench width TW3 that is not equal to the first trench width TW1 or the second trench width TW2.

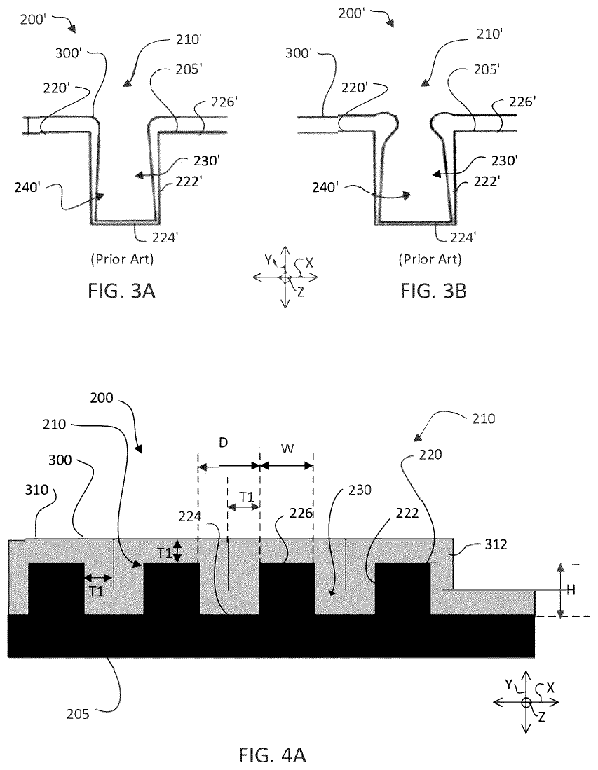

Referring now to FIGS. 3A and 3B, schematic diagram of a structure array 210′ of a component 200′ with a prior art dielectric coating 300′ disposed on the structure array 210′ is provided. As mentioned, thick prior art dielectric coatings 300′ have traditionally been applied onto structure arrays 210′ of a component 200′ with an evaporation deposition process or a flux-controlled deposition process. For example, thick prior art dielectric coatings 300′ have traditionally been applied onto structure arrays 210′ with an evaporation deposition process, a physical vapor deposition (PVD) process (e.g., a sputter deposition), or a flux-controlled chemical vapor deposition (CVD) process (e.g., a plasma-enhanced chemical vapor deposition (PECVD) process). However, the evaporation deposition process, the PVD process, and the flux-controlled CVD process may not provide acceptable coverage and/or quality of the thick dielectric coating 300′ over the structure arrays 210′ of the component 200′.

For example, the PVD and flux-controlled CVD processes rely on local gas flux. Therefore, the flux of reactant molecules can be greater near the entrance of a trench 230′ that is defined between two adjacent features 220′. As such, the entrance of the trench 230′ may became clogged, making it difficult for the reactant molecules to diffuse deeper within the trench 230′. As a result, the PVD and flux-controlled CVD processes may cause the thickness of the dielectric coating 300′ to vary in various locations when applied directly to the structure arrays 210′. For example, and as shown in FIG. 3A, the thickness of the dielectric coating 300′ that is disposed on the ridge 226′ of the plurality of features 220′ may be greater than the thickness of the dielectric coating 300′ that is disposed on the wall 222′ and/or the bottom 224′ of the plurality of features 220′ when the dielectric coating 300′ is disposed directly on the structure array 210 with the PVD or flux-controlled CVD processes. Additionally, or alternatively, and as shown in FIG. 3B, the material of the dielectric coating 300′ may accumulate at the intersection of the ridge 226′ and a respective wall 222′ of the plurality of features 220′ when the dielectric coating 300′ is disposed directly on the structure array 210′ with the PVD or flux-controlled CVD processes.

As a result of the accumulation of material of the dielectric coating 300′ and/or the varying thickness of the dielectric coating 300′, a defect 240′, such as a void or keyhole, may form in the trenches 230′ that are defined between each of the plurality of features 220′. These defects 240′, the varying thickness of the dielectric coating 300′, and/or the accumulation of material of the dielectric coating 300′ may be undesirable. For example, when the component 200′ is a grating for an ion trap, the diffraction efficiency (DE) and/or the refractive index of the grating may be reduced and/or non-uniform throughout the dielectric coating 300′ when a defect 240′ is present, the thickness of the dielectric coating 300′ varies, and/or when material of the dielectric coating 300′ accumulates. As another example, when the component 200′ is a grating for an ion trap, the defects 240′, the varying thickness of the dielectric coating 300′, and/or the accumulation of material of the dielectric coating 300′ may cause scattering points, which can distort the light 120 (FIG. 1) that is emitted by the grating. Additionally, these defects 240′, the varying thickness of the dielectric coating 300′, and/or the accumulation of material of the dielectric coating 300′ may occur more frequently when the aspect ratio (H:W (FIG. 2A)) of the plurality of features 220′ is at least 1:1, such as at least 1:1 and up to 10:1.

As such, an improved method of applying a dielectric coating 300 on a structure array 210 of a component 200 of an electrical device 100 would be welcomed in the art. More specifically, a method of applying a dielectric coating 300 on a structure array 210 of a component 200 of an electrical device 100, the structure array 210 having a plurality of features 220, each of the plurality of features 220 having an aspect ratio (H:W) of at least 1:1 would be welcomed in the art. This method, and the resulting component 200, will be discussed in more detail, below.

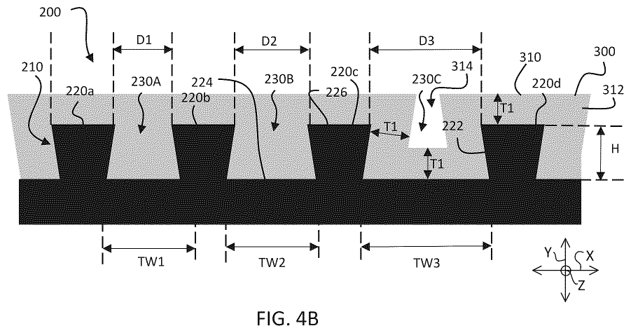

Referring now to FIG. 4A, a schematic diagram of a component 200 is provided, according to an example embodiment. The component 200 can include a structure array 210 and can be configured the same as, or similar to, the component 200 of FIG. 2A. However, in this example, the component 200 includes a dielectric coating 300 disposed on the structure array 210.

Referring still to FIG. 4A, the dielectric coating 300 can include a first layer 310 of a first dielectric material 312. The first layer 310 can have a first thickness T1 and can have a first refractive index. As shown, the first thickness T1 is defined by the thickness of the first layer 310 on a ridge 226 of one of the features 220. In various examples, the first refractive index of the first layer 310 is uniform, or substantially uniform, throughout the first layer 310. For example, the first refractive index of the first layer 310 may vary by less than 0.3 percent, such as less than 0.2 percent, such as less than 0.1 percent throughout the first layer 310. In various examples, the first dielectric material 312 is, or includes, SiO2. In various examples, the first layer 310 of the dielectric coating 300 is applied on the structure array 210 with an atomic layer deposition (ALD) process (e.g., plasma-enhanced ALD or thermal ALD). In various other examples, the first layer 310 of the dielectric coating 300 is applied on the structure array 210 with a PVD or a high-density plasma chemical vapor deposition (HD-PECVD) process. In various examples, the first layer 310 of the dielectric coating 300 is applied on the structure array 210 with a spin-on cladding process.

The ALD process is a deposition technique that may deposit highly conformal coatings on substrates and/or structure arrays with a controlled thickness. The ALD process can include adding a first precursor to a reaction chamber that contains the substrate and/or structure array to be coated. After the first precursor is absorbed by the substrate and/or structure array, the first precursor can be removed from the reaction chamber and a second precursor can be added to the chamber to react with the first precursor, which may create a layer on the surface of the substrate and/or structure array. The second precursor can then be removed from the reaction chamber and the process can be repeated until a desired thickness of the coating is achieved. The ALD process is not a “line-of-sight” deposition technique and not a flux-controlled deposition technique and, as such, may have the ability to “grow” uniform coating on substrates and/or structure arrays that include complex shapes and/or high aspect features.

In various examples, the cladding material may include SiO2, polydimethylsiloxane (PDMS), hydrogen silsesquioxane (HSQ), or a sol-gel, which may be a solution of a metal oxide precursor condensed into a 3D network. In various examples, the spin-on cladding process is a spin-on glass process. Spin-on glass may be a mixture of SiO2 and dopants, such as boron or phosphorous that is suspended in a solvent solution. The spin-on glass process is a deposition technique that deposits highly conformal coatings on substrates and/or structure arrays with a controlled thickness. The spin-on glass process may include spinning the structure array 210 that is formed on a substrate 205 or one or more sublayers on the substrate 205 at a rotational speed of at least 100 revolutions per minute (rpm) and up to 2,000 rpm, such as up to 1,000 rpm, such as up to 400 rpm. Once the structure array 210 is rotating, a volume of spin-on glass material, such as HONEYWELL's ACCUGLASS spin-on glass material, can be dispensed onto the structure array 210. Once the spin-on glass material is dispensed onto the structure array 210, the rotational speed of the structure array 210 can be increased to up to 5,000 rpm, such as up to 4,000 rpm, such as up to 3,000 rpm. The spin-on glass process may include curing the spin-on glass material at a temperature of at least 375 degrees Celsius (° C.) and up to 425° C., for approximately one hour in a nitrogen environment/atmosphere.

As compared to the PVD and/or the flux-controlled CVD processes, the ALD process and/or spin-on cladding process may have the ability to deposit more uniform coatings on high aspect features, such as features 220. As used herein, the term “high aspect features” refers to features that each have an aspect ratio (H:W) that is at least 1:1, such as at least 1:1 and up to 10:1, such as at least 1:1 and up to 5:1. Some examples of high aspect features are features that have an aspect ratio (H:W) of at least 1:1 and up to 4:1, at least 1:1 and up to 3:1, at least 1:1 and up to 2:1, at least 2:1 and up to 5:1, at least 2:1 and up to 4:1, at least 3:1 and up to 5:1, at least 3:1 and up to 4:1, at least 4:1 and up to 8:1, or at least 5:1 and up to 7:1, to name a few examples.

Referring still to FIG. 4A, each feature of the plurality of features 220 may be a high aspect feature having an aspect ratio (H:W) of at least 1:1. Therefore, it may be beneficial to apply the first layer 310 of the dielectric coating 300 with an ALD process or a spin-on cladding process, as opposed to a PVD or flux-controlled CVD process, as previously discussed. In the example of FIG. 4A, and other various examples, the first layer 310 of the dielectric coating 300 is applied with an ALD process or a spin-on cladding process.

In various examples, and with reference to FIG. 4A, the thickness T1 of the first layer 310 can be approximately half of the distance D between one of the plurality of features 220 and an adjacent one of the plurality of features 220. Stated differently, a ratio (T1:D) between the thickness T1 of the first layer 310 and the distance D between one of the plurality of features 220 and an adjacent one of the plurality of features 220 is approximately 0.5:1, such as at least 0.3:1 and up to 0.7:1, such as at least 0.4:1 and up to 0.6:1.

Having a T1:D ratio that is approximately 0.5:1 may be beneficial for several reasons. First, having a T1:D ratio that is approximately 0.5:1 may ensure that the trenches 230 that are defined between the features 220 are filled substantially, or completely, with the first layer 310 of the dielectric coating 300. Second, having a T1:D ratio that is approximately 0.5:1 may ensure that the thickness T1 is uniform throughout the component 200. For example, having a T1:D ratio that is approximately 0.5:1 may ensure that the thickness T1 of the first layer 310 of the dielectric coating 300 on the wall 222 of a feature 220 is substantially similar to (e.g., within one percent) a thickness T1 of the first layer 310 of the dielectric coating 300 on a ridge 226 of a feature 220 and/or on a bottom 224 of a trench 230.

In various examples, the thickness T1 of the first layer 310 can be greater than the height H of at least one of the features 220. Stated differently, a ratio (T1:H) between a thickness T1 of the first layer 310 and a height H of at least one of the features 220 can be at least 1:1. For example, the T1:H ratio can be at least 1:1 and up to 5:1, such as at least 1:1 and up to 3:1, such as at least 1:1 and up to 2:1. In various examples, having a T1:H ration that is at least 1:1 may ensure that the trenches 230 between each of the features 220 is filled substantially, or completely, with the first layer 310 of the dielectric coating.

Referring now to FIG. 4B, a schematic diagram of a component 200 is provided, according to an example embodiment. The component 200 can include a structure array 210 and can be configured the same as, or similar to, the component 200 of FIG. 2C. However, in this example, the component 200 includes a dielectric coating 300 disposed on the structure array 210. The dielectric coating 300 can include a first layer 310 of a first dielectric material 312. The first layer 310 can have a first thickness T1 and can have a first refractive index. As shown, the first thickness T1 is defined by the thickness of the first layer 310 on a ridge 226 of one of the features 220. In various examples, the thickness T1 of the first layer 310 of the dielectric coating 300 on the wall 222 of a feature 220 is substantially similar to (e.g., within one percent) a thickness T1 of the first layer 310 of the dielectric coating 300 on a ridge 226 of a feature 220 and/or on a bottom 224 of a trench 230.

When the distances D1, D2, D3 between adjacent features 220 are varied such that at least one of distance D1, distance D2, and distance D3 is different than another one of distance D1, distance D2, and distance D3, the trenches between each of the features 220 may not completely fill. As such, one or more gaps 314 may form between the first layer 310 of the dielectric coating 300 of adjacent features, such as feature 220c and feature 220d. For example, when a ratio (D:T1) between a distance D between features and the first thickness T1 of the first layer 310 is greater than 2:1, a gap 314 may form between those features 220. Also, when a ratio (TW:T1) between a trench width TW and the first thickness T1 of the first layer 310 is greater than 2:1, a gap 314 may form between those features 220.

As will be discussed further, a second layer 320 of a second dielectric material 322 can be applied to the first layer 310 of a first dielectric material 312. Prior to applying the second layer 320 of the second dielectric material 322, an etching process can be performed on the first layer 310. Performing the etching process on the first layer 310 may remove layers of the first dielectric material 312. In various examples, an ion beam etching process can be performed on the first layer 310. The ion beam etching process can include accelerating a beam of ions at the first layer 310 in a low-pressure environment. The accelerated ions may transfer their kinetic energy to the first layer 310, which may cause layers of the first dielectric material 312 to be ejected and removed.

Performing an etching process on the first layer 310 when gaps 314 have formed within the first layer 310 may widen the gaps 314, which may be beneficial when the second layer 320 is subsequently applied to the first layer 310. For example, performing the etching process to widen the gaps 314 may increase the likelihood that the second layer 320 can fully fill the gap 314.

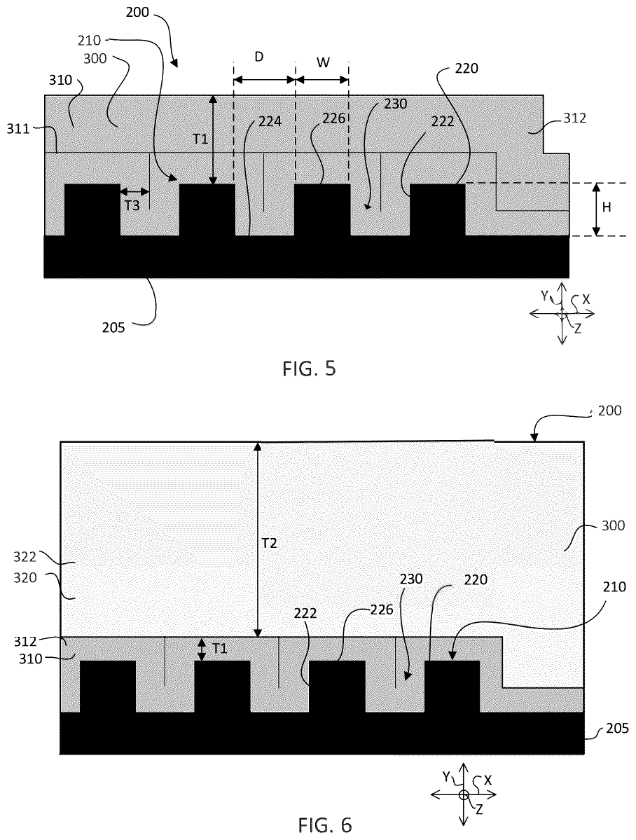

Referring now also to FIG. 5, a schematic diagram of the component 200 of the electrical device 100 of FIG. 1 is provided, according to an example embodiment. The component 200 of FIG. 5 may be configured similarly to, or the same as, the component 200 of FIG. 4A. However, in this example, a thickness T3 of the first layer 310 on the walls 222 of the features 220 are different than the thickness T1 on the ridge 226 of the features 220. More specifically, the thickness T3 of the first layer 310 on the walls 222 of the features 220 are less than the thickness T1 on the ridge 226 of the features 220. In various examples, a ratio (T3:D) between the thickness T3 of the first layer 310 on the walls 222 of the features 220 and the distance D between one of the plurality of features 220 and an adjacent one of the plurality of features 220 is approximately 0.5:1, such as at least 0.3:1 and up to 0.7:1, such as at least 0.4:1 and up to 0.6:1, whereas a ratio (T1:D) between the thickness T1 of the first layer 310 on the ridge 226 of the features 220 and the distance D between one of the plurality of features 220 and an adjacent one of the plurality of features 220 is greater than 0.5:1, such as greater than 0.5:1 and up to 4:1, such as greater than 0.5:1 and up to 2:1, such as greater than 0.5:1 and up to 1:1.

Having a T3:D ratio that is approximately 0.5:1 and a T1:D ratio that is greater than 0.5:1 has several benefits. First, the thickness T3 of the first layer 310 is great enough to substantially, or completely, fill the trenches 230 between the features 220. Additionally, once the thickness of the first layer 310 exceeds half of the distance D (indicated by sublayer 311), the first dielectric material 312 that is deposited after sublayer 311 no longer needs to fill the trenches 230, which may create a more uniform surface along a plane defined by the X direction and the Z direction.

Referring still to FIG. 5, each of the plurality of features 220 can have an aspect ratio (H:W) that is at least 1:1, such as at least 1:1 and up to 10:1, as previously mentioned. In various examples, the height H of each of the plurality of features 220 is at least 100 nanometers (nm) and up to 500 nm, such as at least 150 nm and up to 300 nm, such as at least 200 nm and up to 250 nm.

As also mentioned, the component 200 can have a T3:D ratio that is approximately 0.5:1. In various examples, the thickness T3 can be at least 100 nm and up to 500 nm, such as at least 150 nm and up to 300 nm, such as at least 200 nm and up to 250 nm.

Additionally, and as previously mentioned, the component 200 can have a T1:D ratio that is greater than 0.5:1. In various examples, the thickness T1 can be at least 100 nm and up to 1,000 nm, such as at least 100 nm and up to 800 nm, such as at least 100 nm and up to 500 nm, such as at least 100 nm and up to 400 nm, such as at least 200 nm and up to 400 nm.

Referring now to FIG. 6, a schematic diagram of the component 200 of the electrical device 100 of FIG. 1 is provided, according to an example embodiment. The component 200 can include the dielectric coating 300 disposed on the structure array 210 and can be configured the same as, or similar to, the component 200 of FIG. 4A or FIG. 5. However, in this example, the dielectric coating 300 includes a second layer 320 of a second dielectric material 322 in addition to the first layer 310 of the first dielectric material 312.

The second layer 320 has a second thickness T2 and has a second refractive index. In various examples, the second dielectric material 322 can be, or can include, SiO2. In various examples, the second layer 320 of the dielectric coating 300 can be applied on the first layer 310 with a deposition process that is not an ALD process or a spin-on cladding process. In various examples, the second layer 320 of the dielectric coating 300 can be applied on the first layer 310 with an evaporation deposition process, a PVD process, or a flux-controlled CVD process. For example, the second layer 320 of the dielectric coating 300 can be applied on the first layer 310 with a PECVD process. In various examples, the second refractive index of the second layer 320 is uniform, or substantially uniform, throughout the second layer 320. For example, the second refractive index of the second layer 320 may vary by less than 0.3 percent, such as less than 0.2 percent, such as less than 0.1 percent throughout the second layer 320.

In various examples, the second thickness T2 of the second layer 320 can be greater than the first thickness T1 of the first layer 310. Stated differently, a ratio (T2:T1) between the second thickness T2 and the first thickness T1 can be greater than 1:1, such as at least 1:1 and up to 300:1, such as at least 1:1 and up to 250:1, such as at least 1:1 and up to 150:1, such as at least 1:1 and up to 100:1, such as at least 10:1 and up to 100:1. For example, the T2:T1 ratio can be at least 100:1 and up to 300:1, at least 100:1 and up to 300:1, at least 100:1 and up to 200:1, at least 150:1 and up to 200:1, or at least 200:1 and up to 300:1, to name a few examples.

In various examples, the second thickness T2 of the second layer 320 can be approximately equal to the first thickness T1 of the first layer 310. For example, the second thickness T2 can be within ten percent, such as within five percent, such as within two percent of the thickness of the first thickness T1.

In various examples, the second thickness T2 of the second layer 320 can be at least 5,000 nm, such as at least 5,000 nm and up to 30,000 nm. For example, the thickness T2 of the second layer 320 can be at least 5,000 nm and up to 25,000 nm, at least 10,000 nm and up to 30,000 nm, or at least 5,000 and up to 10,000, to name a few examples.

As mentioned, the first layer 310 of the dielectric coating 300 can be applied with an ALD process or a spin-on cladding process, whereas the second layer 320 of the dielectric coating 300 can be applied with an evaporation deposition process, a PVD process, or a flux-controlled CVD process. In various embodiments, the first dielectric material 312 of the first layer 310 may be the same as the second dielectric material 322 of the second layer 320. For example, the first dielectric material 312 of the first layer 310 and the second dielectric material 322 of the second layer 320 can both be, or include, SiO2. However, even if the first dielectric material 312 of the first layer 310 is the same as the second dielectric material 322 of the second layer 320, the first refractive index (n1) of the first layer 310 may differ from the second refractive index (n2) of the second layer 320 when the first layer 310 is applied with an ALD process or a spin-on cladding process and the second layer 320 is applied with an evaporation deposition process, a PVD process, or a flux-controlled CVD process. As will be appreciated, materials applied with an ALD process or a spin-on cladding process may have a different refractive index than materials applied with an evaporation deposition process, a PVD process, or a flux-controlled CVD process, even when the materials applied are the same. Therefore, the first refractive index (n1) of the first layer 310 may be different than the second refractive index (n2) of the second layer 320. For example, the percent difference between the first refractive index (n1) and the second refractive index (n2) may be greater than 0 and up to 0.5 percent, where the percent difference between the first refractive index (n1) and the second refractive index (n2) is calculated by the formula (|n1−n2|)/((n1+n2)/2)*100.

In various examples, the first refractive index (n1) of the first layer 310 may be greater than the second refractive index (n2) of the second layer 320. For example, the first refractive index (n1) may be at least 0.5 percent and up to 10 percent greater than the second refractive index (n2). In various examples, the second refractive index (n2) of the second layer 320 may be greater than the first refractive index (n1) of the first layer 310. For example, the second refractive index (n2) may be at least 0.5 percent and up to 10 percent greater than the first refractive index (n1).

In various examples, a refractive index (n0) of the substrate 205 and/or the structure array 210 can be different than the first refractive index (n1) of the first layer 310 and/or the second refractive index (n2) of the second layer 320. For example, the percent difference between the refractive index (n0) of the substrate 205 and/or the structure array 210 and the first refractive index (n1) and/or the second refractive index (n2) can be greater than five percent, such as at least fifteen percent and up to one hundred and fifty percent, such as at least fifteen percent and up to one hundred percent, such as at least twenty percent and up to thirty percent.

As will be appreciated, applying a first layer 310 of the dielectric coating 300 with an ALD process or a spin-on cladding process and applying a second layer 320 of the dielectric coating 300 with an evaporation deposition process, a PVD process, or a flux-controlled CVD process has several benefits. First, and as explained, the ALD process or a spin-on cladding process may provide high conformity, especially with high aspect features. Therefore, applying the first layer 310 of the dielectric coating 300 with an ALD process or a spin-on cladding process may allow for the dielectric coating 300 to be applied with a relatively high conformity, in comparison to if the dielectric coating 300 was applied with only an evaporation deposition process, a PVD process, or a flux-controlled CVD process. In various examples, the spin-on cladding process may allow for the dielectric coating 300 to be applied with a relatively high conformity and substantially or completely fill trenches between features with re-entrant profiles.

Second, the evaporation deposition process, the PVD process, and the flux-controlled CVD process may be quicker and may cost less than the ALD process or a spin-on cladding process. As such, applying the second layer 320 of the dielectric coating 300 with an evaporation deposition process, a PVD process, or a flux-controlled CVD process may allow for the dielectric coating 300 to be applied quicker and cheaper than if only an ALD process or a spin-on cladding process was used. Therefore, applying the first layer 310 of the dielectric coating 300 with an ALD process or a spin-on cladding process and the second layer 320 of the dielectric coating 300 with an evaporation deposition process, a PVD process, or a flux-controlled CVD process may result in applying the dielectric coating 300 to the component 200 quicker and/or cheaper and/or more compliant than if only one of an ALD process, a spin-on cladding process, an evaporation deposition process, a PVD process, or a flux-controlled CVD was used.

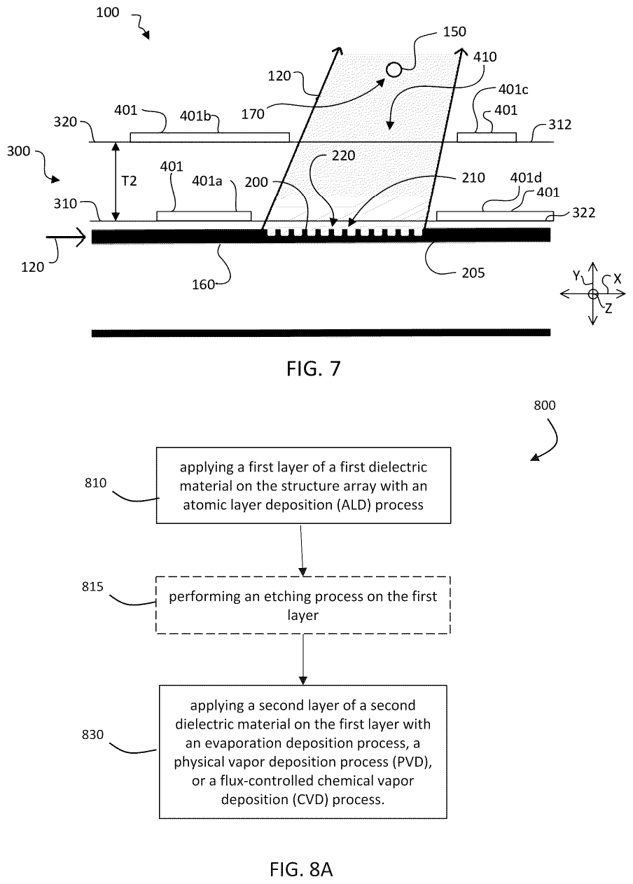

Referring now to FIG. 7, a schematic diagram of an electrical device 100 is provided, according to an example embodiment. The electrical device 100 of FIG. 7 can be configured the same as, or similar to, the electrical device 100 of FIG. 1. In this example, the electrical device 100 is an ion trap and includes a dielectric coating 300, which includes a first layer 310 and a second layer 320. The dielectric coating 300 of FIG. 7 can be configured the same as, or similar to, the dielectric coating 300 as previously described in relation to FIG. 6.

As shown in FIG. 7, the electrical device 100 can include at least two electrodes 401. For example, the electrical device 100 can include a first electrode 401a that is positioned between the first layer 310 and the second layer 320 of the dielectric coating 300, and a second electrode 401b that is positioned on the second layer 320 of the dielectric coating 300. In some examples, the electrical device 100 can include more than two electrodes 401, such as at least four electrodes 401. For example, the electrical device 100 can include the first electrode 401a, the second electrode 401b, a third electrode 401c that is on the second layer 320 of the dielectric coating 300, and a fourth electrode 401d that is positioned between the first layer 310 and the second layer 320 of the dielectric coating 300.

In other examples, the electrical device 100 may not include electrodes 401 between the first layer 310 and the second layer 320. For example, the electrical device 100 can include at least one electrode 401, such as the first electrode 401a, that is positioned on the second layer 320 of the dielectric coating 300 and at least one electrode 401, such as second electrode 401b, that is positioned on a third layer (not shown) of the dielectric coating 300.

When the component 200 is an ion trap, for example, the electrodes 401 can be positioned to form a window 410. In the example of FIG. 7, the first electrode 401a and the fourth electrode 401d are spaced apart a sufficient distance on the first layer 310 of the dielectric coating 300 to allow the light 120 to be directed from the component 200, which in this example is a grate of the ion trap, to the trapping zone 170 to trap the at least one atomic ion 150. Additionally, the second electrode 401b and third electrode 401c are spaced apart a sufficient distance on the second layer 320 of the dielectric coating 300 to allow the light 120 to be directed from the component 200 to the trapping zone 170.

In various examples, at least one of the electrodes 401 can be configured as a ground electrode and another one of the electrodes 401 can be configured as a control electrode or a radio frequency drive electrode. For example, electrode 401a and/or electrode 401d can be configured as a ground electrode, and electrode 401b and/or electrode 401c can be configured as a control electrode or a radio frequency drive electrode. As will be appreciated, it may be beneficial to provide sufficient insulation between ground electrodes and control electrodes or radio frequency drive electrodes. As will also be appreciated, a dielectric material, such as second dielectric material 322 of the second layer 320 of the dielectric coating 300 may provide sufficient insulation between ground electrodes and control electrodes. In various examples, the thickness T2 of the second layer 320 of the dielectric coating 300 may be tailored to provide a sufficient amount of insulation between the at least one ground electrode, such as electrode 401a and/or electrode 401d, and the at least one control electrode, such as electrode 401b or electrode 401c.

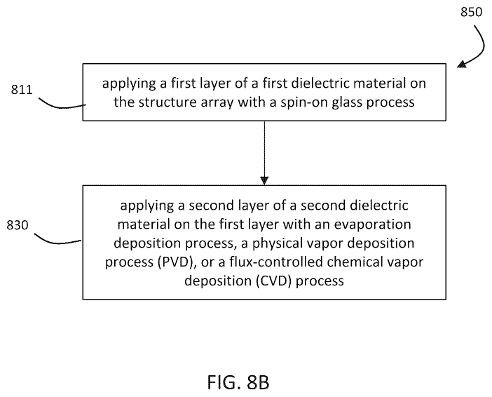

Referring now to FIG. 8A, a flowchart of a method 800 of applying a dielectric coating 300 on a structure array 210 of a component 200, such as the component 200 of FIG. 6, of an electrical device 100 is provided, according to an example embodiment. In various examples, the structure array 210 can be formed on a substrate 205 or on one or more sublayers, and the structure array 210 can have a plurality of features 220. The method 800 can include the step 810 of applying a first layer 310 of a first dielectric material 312 on the structure array 210 with an ALD process. The method may include a step 815 of performing an etching process, such as an ion beam etching process, on the first layer. The method 800 can additionally include the step 830 of applying a second layer 320 of a second dielectric material 322 on the first layer 310 with an evaporation deposition process, a PVD process, or a flux-controlled CVD process. In various examples, the second layer 320 has a second thickness that is greater than the first thickness. In various examples, the method 800 can include performing chemical mechanical planarization on the first layer 310 prior to applying the second layer 320 of the second dielectric material 322 on the first layer 310. Performing chemical mechanical planarization on the first layer 310 may allow the second layer 320 to adhere better to the first layer 310. In various examples, the method 800 can include performing chemical mechanical planarization on the second layer 320.

Referring now to FIG. 8B, a flowchart of a method 850 of applying a dielectric coating 300 on a structure array 210 of a component 200 of an electrical device 100 is provided, according to an example embodiment. In various examples, the structure array 210 can be formed on a substrate 205 or on one or more sublayers formed on the substrate 205, and the structure array 210 can have a plurality of features 220. The method 850 can include the step 811 of applying a first layer 310 of a first dielectric material 312 on the structure array 210 with a spin-on cladding process. The method 800 can include the step 830 of applying a second layer 320 of a second dielectric material 322 on the first layer 310 with an evaporation deposition process, a PVD process, or a flux-controlled CVD process. In various examples, the second layer 320 has a second thickness that is greater than the first thickness. In various examples, the method 850 can include performing chemical mechanical planarization on the first layer 310 prior to applying the second layer 320 of the second dielectric material 322 on the first layer 310. Performing chemical mechanical planarization on the first layer 310 may allow the second layer 320 to adhere better to the first layer 310. In various examples, the method 850 can include performing chemical mechanical planarization on the second layer 320.

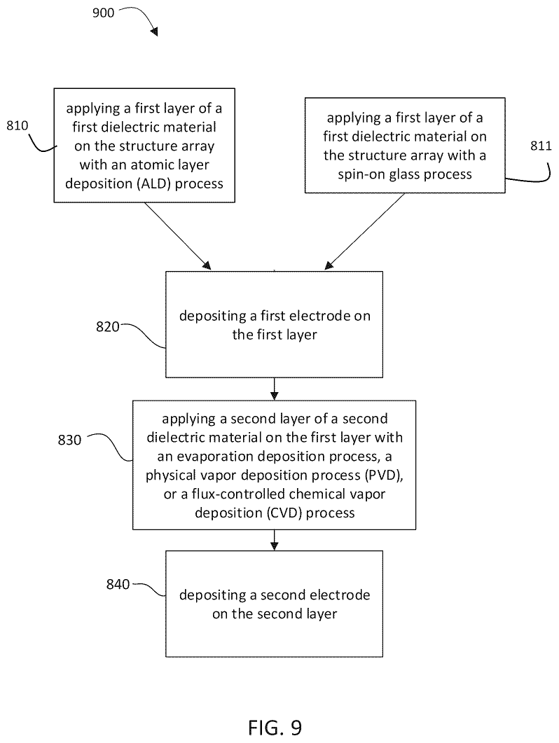

Referring now to FIG. 9, a flowchart of a method 900 of applying a dielectric coating 300 on a structure array 210 of a component 200 of an electrical device 100, such as the electrical device 100 of FIG. 7, is provided, according to an example embodiment. The method 900 can be the same as, or similar to, the method 800 of FIG. 8A and includes the step 810 or the method 850 of FIG. 8B and includes the step 811. However, method 900 further includes the step 820 of depositing a first electrode 401a on the first layer 310 after step 820. Additionally, method 900 further includes the step 840 of depositing a second electrode 401b on the second layer 320 after step 830.

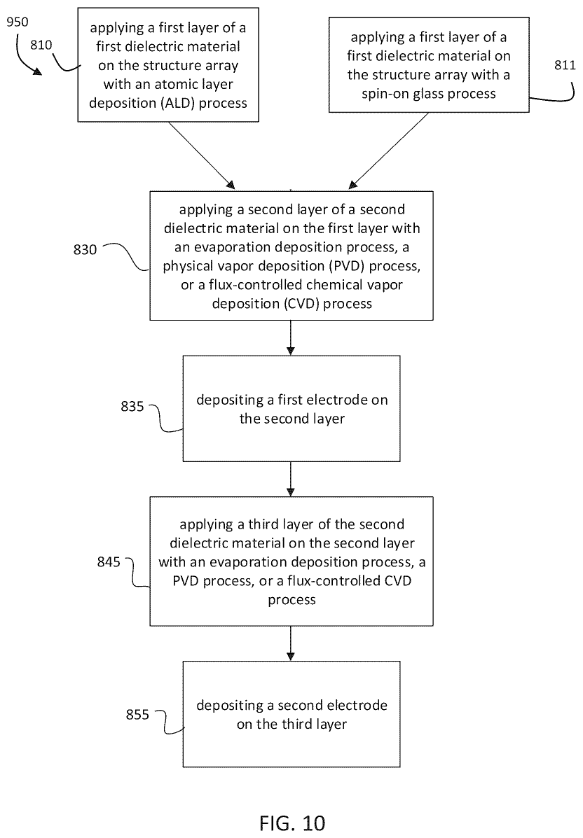

Referring now to FIG. 10, a flowchart of a method 900 of applying a dielectric coating 300 on a structure array 210 of a component 200 of an electrical device 100, such as the electrical device 100 of FIG. 7, is provided, according to an example embodiment. The method 950 can be the same as, or similar to, the method 800 of FIG. 8A and includes the step 810 or the method 850 of FIG. 8B and includes the step 811. However, the method 950 can include a step 835 of depositing a first electrode 401a on the second layer 320. Additionally, the method 950 can include the step 845 of applying a third layer of the second dielectric material 322 on the second layer 320 with an evaporation deposition process, a PVD process, or a flux-controlled CVD process. The method 950 can also include the step 855 of depositing a second electrode 401b on the third layer.

Many modifications and other embodiments of the invention set forth herein will come to mind to one skilled in the art to which the invention pertains having the benefit of the teachings presented in the foregoing descriptions and the associated drawings. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation.

That which is claimed:

1. A method of applying a dielectric coating on a structure array of a component of an electrical device, the structure array having a plurality of features, the method comprising:
applying a first layer of a first dielectric material on the structure array with a spin-on cladding process, the first layer having a first thickness.

2. The method of claim 1, wherein at least one of the substrate or the structure array comprise at least one of Aluminum Oxide (Al2O3), Titanium dioxide (TiO2), silicon (Si), or silicon nitride (Si3N4).

3. The method of claim 1, wherein the electrical device is an ion trap and the component is a or a photonic component of the ion trap.

4. The method of claim 1, wherein at least one of the features of the plurality of features is spaced apart from another one of the plurality of features by a distance, wherein a ratio between the first thickness of the first layer and the distance is at least 0.4:1 and up to 0.6:1.

5. The method of claim 1, further comprising applying a second layer of a second dielectric material on the first layer with an evaporation deposition process, a physical vapor deposition process (PVD), or a flux-controlled chemical vapor deposition (CVD) process, the second layer having a second thickness that is greater than the first thickness.

6. The method of claim 5, wherein at least one of the first dielectric material or the second dielectric material comprises silicon dioxide (SiO2).

7. The method of claim 5, wherein the first dielectric material has a first refractive index and the second dielectric material has a second refractive index, and wherein one of the first refractive index or the second refractive index is greater than the other of the first refractive index or the second refractive index.

8. The method of claim 5, wherein the first dielectric material has a first refractive index and the second dielectric material has a second refractive index, wherein a percent difference between the first refractive index and the second refractive index is less than 0.5 percent.

9. The method of claim 5, wherein the first dielectric material and the second dielectric material are the same.

10. The method of claim 5, wherein the first dielectric material and the second dielectric material are different.

11. The method of claim 5, wherein the spin-on cladding process is an ion beam spin-on glass process.

12. The method of claim 5, wherein a ratio (T1:H) between the first thickness of the first layer and a height of at least one of the features is at least 1:1.

13. The method of claim 5, further comprising:
depositing a first electrode on the second layer;
applying a third layer of a third dielectric material on the second layer with an evaporation deposition process, a PVD process, or a flux-controlled CVD process; and
depositing a second electrode on the third layer.

14. A method of applying a dielectric coating on a structure array of a component of an electrical device, the structure array having a plurality of features, the method comprising:
applying a first layer of a first dielectric material on the structure array with an atomic layer deposition (ALD) process or a spin-on cladding process, the first layer having a first thickness;
removing at least a portion of the first layer with an etching process; and
applying a second layer of a second dielectric material on the first layer, the second layer having a second thickness that is greater than the first thickness.

15. The method of claim 14, wherein the second layer is applied with an evaporation deposition process, a plasma-enhanced chemical vapor deposition (PECVD) process, or a flux-controlled chemical vapor deposition (CVD) process.

16. The method of claim 14, wherein at least one of the features of the plurality of features is spaced apart from another one of the plurality of features by a distance, wherein a ratio between the first thickness of the first layer and the distance is at least 0.4:1 and up to 0.6:1.

17. The method of claim 14, wherein at least one of the first dielectric material or the second dielectric material comprises silicon dioxide (SiO2).

18. The method of claim 14, wherein the electrical device is an ion trap and the component is a or a photonic component of the ion trap.

19. The method of claim 14, wherein a first distance is defined by at least a first pair of adjacent features of the plurality of features and a second distance is defined by at least a second pair of adjacent features of the plurality of features, and wherein the second distance is greater than the first distance.

20. The method of claim 14, wherein a ratio between the second thickness and the first thickness is at least 10:1 and up to 300:1.
